(19) United States
(12) Patent Application Publication
(10) Pub. No.: US 2014/0042548 A1
(43) Pub. Date: Feb. 13, 2014

(54) DRAM STRUCTURE WITH BURIED WORD LINES AND FABRICATION THEREOF, AND IC STRUCTURE AND FABRICATION THEREOF

(71) Applicant: NANYA TECHNOLOGY CORPORATION, Taoyuan (TW)

(72) Inventors: Hao-Chieh Liu, Taipei City (TW); Lars Heineck, Garden City, ID (US); Ping-Chieh Chiang, Taipei County (TW)

(73) Assignee: NANYA TECHNOLOGY CORPORATION, Taoyuan (TW)

(21) Appl. No.: 14/047,018

(22) Filed: Oct. 7, 2013

Related U.S. Application Data
(62) Division of application No. 13/109,002, filed on May 17, 2011.

(51) Int. Cl. H01L 27/108

(52) U.S. Cl. CPC H01L 27/108
USPC 257/368

(57) ABSTRACT

A DRAM structure with buried word lines is described, including a semiconductor substrate, cell word lines buried in the substrate and separated from the same by a first gate dielectric layer, and isolation word lines buried in the substrate and separated from the same by a second gate dielectric layer. The top surfaces of the cell word lines and those of the isolation word lines are lower than the top surface of the substrate. The bottom surfaces of the isolation word lines are lower than those of the cell word lines.

### CROSS-REFERENCE TO RELATED APPLICATION

This application is a divisional of and claims priority benefit of an application Ser. No. 13/109,002, filed on May 17, 2011, now pending. The entirety of the above-mentioned patent application is hereby incorporated by reference herein and made a part of this specification.

### BACKGROUND OF THE INVENTION

1. Field of Invention

This invention relates to a dynamic random access memory (DRAM) structure with buried word lines and a process of fabricating the same, and to an integrated circuit (IC) structure and a process of fabricating the same.

2. Description of Related Art

A conventional DRAM cell includes a transistor and a capacitor coupled thereto. When the integration degree of DRAM increases beyond a certain level, the channel length of a traditional planar transistor is reduced to cause the short channel effects that include the drain-induced barrier lowering (DIBL) and so forth. The shrinking of the device size also reduces the distance between word lines and bit lines, and eventually induces parasitic capacitance to build up between such word lines and bit lines.

A buried word line (buried-WL) DRAM structure having word lines buried in the substrate is one approach to deal with the problem. FIG. 1 shows a conventional buried-WL DRAM structure, which includes a semiconductor substrate 100 with trenches 110 therein, a plurality of cell word lines 120a in some of the trenches 110 for controlling the transistors in the cells. The conventional buried-WL DRAM structure as shown in FIG. 1 further has a plurality of isolation word lines 120b in other trenches 110, a gate dielectric layer 130 separating each word line 120a or 120b from the substrate 100, a plurality of common source regions 140a each shared by two cells, and a plurality of drain regions 140b. It is noted that the capacitors coupled to the drain regions 140b and the bit lines coupled to the common source regions 140a are omitted in the figure for simplicity.

The isolation word lines 120b are applied with a voltage independent from the voltage on the cell word lines 120a to reduce the static and dynamic coupling between adjacent cells. However, when the structure is further scaled down, the conventional design of isolation word lines is insufficient in the isolation effect.

On the other hand, there are certain other IC structures with conductors buried in the substrate. The buried conductors are usually separated from the substrate by an insulator when the material of the substrate is not insulating.

### SUMMARY OF THE INVENTION

Accordingly, this invention provides a DRAM structure with buried word lines.

This invention also provides a fabricating process of the DRAM structure.

This invention further provides an integrated circuit (IC) structure with buried conductors that covers the DRAM structure in scope, and a fabricating process thereof.

The DRAM structure of this invention includes a semiconductor substrate, a plurality of cell word lines buried in the substrate and separated from the same by a first gate dielectric layer, and a plurality of isolation word lines buried in the substrate and separated from the same by a second gate dielectric layer. The top surfaces of the cell word lines and those of the isolation word lines are lower than the surface of the substrate. The bottom surfaces of the isolation word lines are lower than those of the cell word lines.

In an embodiment, the top surfaces of the isolation word lines are substantially coplanar with those of the cell word lines. In anther embodiment, the top surfaces of the isolation word lines are lower than the top surfaces of the cell word lines but higher than the bottom surfaces of the cell word lines. In still another embodiment, the top surfaces of the isolation word lines are substantially coplanar with the bottom surfaces of the cell word lines, or are even lower than the bottom surfaces of the cell word lines. Usually, the cell word lines are divided into a plurality of pairs of cell word lines, and each pair is separated from a neighboring pair by an isolation word line.

The fabricating process of a DRAM structure with buried word lines of this invention is described as follows. A plurality of first trenches and a plurality of second trenches deeper than the first trenches are formed in a semiconductor substrate. A gate dielectric layer is formed in each of the first and the second trenches. Cell word lines are formed in the first trenches and isolation word lines formed in the second trenches.

In an embodiment, the first trenches and the second trenches with two different depths are defined by two lithography processes. A first mask layer having therein patterns of the first trenches and patterns of the second trenches is formed over the substrate. A second mask layer is formed covering the patterns of the first trenches. The substrate is etched using the first and the second mask layers as a mask to form the second trenches. After the second mask layer is removed, the substrate is etched using the first mask layer as a mask to form the first trenches and deepen the second trenches.

In another embodiment, the first trenches and the second trenches with different depths are defined by one lithography process. A plurality of mask patterns is formed over the substrate. A first spacer is formed on the sidewalls of each mask pattern. A second spacer is formed on the sidewall of each first spacer. The substrate is etched using the mask patterns, the first spacers and the second spacers as a mask to form the second trenches. Top portions of the mask patterns, top portions of the first spacers and top portions of the second spacers are removed. The remaining first spacers are removed. The substrate is etched using the remaining mask patterns and the remaining second spacers as a mask to form the first trenches and deepen the second trenches.

Since the bottom surfaces of the isolation word lines are lower than those of the cell word lines, the isolation effect between adjacent cells is improved. Further, when the top surfaces of the isolation word lines are lower than those of the cell word lines, the parasitic capacitance between the isolation word lines and the cell word lines and that between the isolation word lines and the bit lines are both decreased.

The IC structure with buried conductors of this invention includes a substrate, a plurality of first conductors buried in the substrate, and a plurality of second conductors buried in the substrate. The bottom surfaces of the second conductors are lower than those of the first conductors.

The fabricating process of an IC structure of this invention is described below. A plurality of first trenches and a plurality of second trenches deeper than the first trenches are formed in a substrate. A plurality of first conductors is formed in the first trenches and a plurality of second conductors formed in the second trenches. The first trenches and the second trenches may be defined by one or two lithography processes as mentioned above.

In order to make the aforementioned and other objects, features and advantages of this invention comprehensible, a preferred embodiment accompanied with figures is described in detail below.

### BRIEF DESCRIPTION OF THE DRAWINGS

FIG. 1 is a cross-sectional view of a conventional buried-WL DRAM structure.

FIG. 2 is a cross-sectional view of a buried-WL DRAM structure according to a first embodiment of this invention.

FIG. 3 is a cross-sectional view of a buried-WL DRAM structure according to a second embodiment of this invention.

FIG. 4 is a cross-sectional view of a buried-WL DRAM structure according to a third embodiment of this invention.

FIGS. 5A-5D illustrate, in a cross-sectional view, a process of fabricating a buried-WL DRAM structure according to a fourth embodiment of this invention, wherein the trenches of different depths are defined by two lithography processes.

FIGS. 6A-6H illustrate, in a cross-sectional view, a fabricating process of a buried-WL DRAM structure according to a fifth embodiment of this invention, wherein the trenches of different depths are defined by one lithography process.

### DESCRIPTION OF EMBODIMENTS

This invention is further explained with the following embodiments referring to the accompanying drawings, which are not intended to limit the scope of this invention. Specifically, although the following embodiments all relate to DRAM structures with buried lines and their fabrications, this invention can be readily applied to various other IC structures with buried conductors and their fabrications based on the teachings of the following descriptions for the embodiments.

### Embodiments 1-3: Buried-WL DRAM Structures

FIG. 2 is a cross-sectional view of a buried-WL DRAM structure according to a first embodiment of this invention.

Referring to FIG. 2, the DRAM structure includes a semiconductor substrate 200 having a plurality of first trenches 210a and a plurality of second trenches 210b deeper than the first trenches 210a, a plurality of cell word lines 220a, a plurality of isolation word lines 220b, a gate dielectric layer 230, a plurality of common source regions 240a and a plurality of drain regions 240b. The cell word lines 220a are disposed in the first trenches 210a and separated from the substrate 200 by the gate dielectric layer 230. The isolation word lines 220b are disposed in the second trenches 210b and separated from the substrate 200 by the gate dielectric layer 230.

The top surfaces 222a of the cell word lines 220a and the top surfaces 222b of the isolation word lines 220b are lower than the top surface 202 of the substrate 200. The bottom surfaces 224b of the isolation word lines 220b are lower than the bottom surfaces 224a of the cell word lines 220a. The common source regions 240a and the drain regions 240b are formed in portions of the substrate 200 between the trenches 210a/b.

Each isolation word line 220b is disposed between two cell word lines 220a. The cell word lines 220a are divided into a plurality of pairs of cell word lines, and each pair is separated from a neighboring pair by an isolation word line 220b.

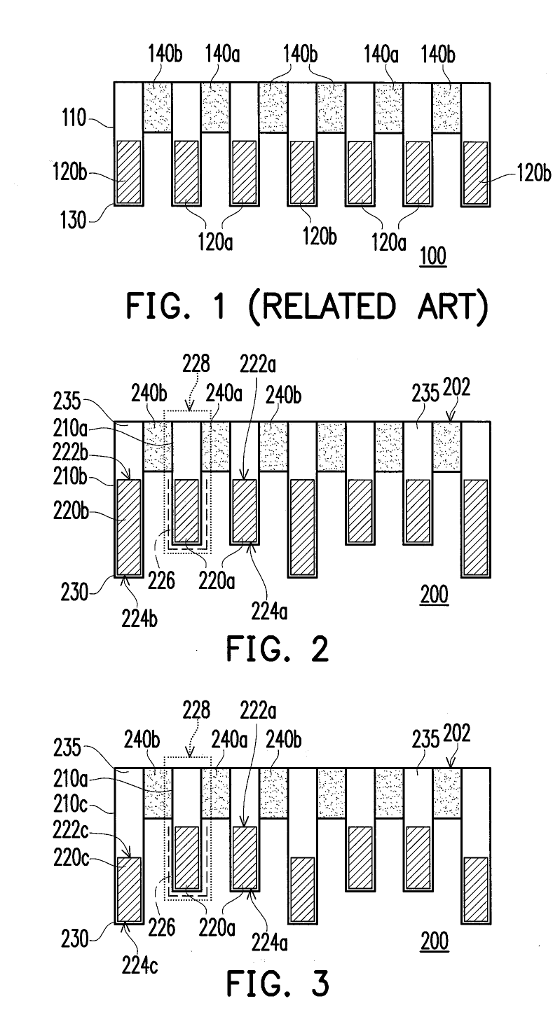

The drain region 240b, a common source region 240a, a portion of a cell word line 220a between them, the gate dielectric layer 230 and the channel 226 beside the portion of the cell word line 220a constitute a MOSFET transistor 228. Each common source regions 240a is shared by a pair of neighboring memory cells. It is noted that the capacitors coupled to the drain regions 240b and the bit lines coupled to the common source regions 240a are omitted in the figure for simplicity, as in the case of FIG. 1.

In this embodiment, the top surfaces 222b of the isolation word lines 220b are substantially coplanar with the top surfaces 222a of the cell word lines 220a. The cell word lines 220a and the isolation word lines 220b may both include a metallic material, such as titanium nitride (TiN), tantalum nitride (TaN), W or poly-Si, for reducing the electrical resistance. The gate dielectric layers 230 may include silicon dioxide (SiO₂) or SiN.

The distance between the top surface of each word line 220a/b and the top surface 202 of the substrate 200 ranges from 700 to 800 angstroms, and the thickness of each cell word line 220a ranges from 700 to 800 angstroms. It is feasible that the bottom surfaces 224b of the isolation word lines 220b are lower than the bottom surfaces 224a of the cell word lines 220a by no more than 800 angstroms.

Though in the first embodiment the top surfaces 222b of the isolation word lines 220b are substantially coplanar with the top surfaces 222a of the cell word lines 220a, the top surfaces of the isolation word lines may alternatively be lower than those of the cell word lines to reduce the overlap area between them and the cell word lines as well as to increase the distance between them and the bit lines. As a result, the parasitic capacitance between the isolation word lines and the cell word lines and that between the isolation word lines and the bit lines both can be reduced to improve the performance of the DRAM. Two such cases are described below, as second and third embodiments of this invention.

FIG. 3 is a cross-sectional view of a buried-WL DRAM structure according to the second embodiment of this invention.

Referring to FIG. 3, the second embodiment is different from the first one in that the top surfaces 222c of the isolation word lines 220c are lower than the top surfaces 222a of the cell word lines 220a but higher than the bottom surfaces 224a of the same, while the difference between the depth of the bottom surfaces 224c of the isolation word lines 220c and the bottom surfaces 224a of the cell word lines 220a may be the same as that in the first embodiment.

Nevertheless, the second trenches 210c may alternatively be formed deeper than the second trenches 210b formed in the first embodiment to maintain the thickness of the isolation word lines 220c and the electrical conductivity of the same.

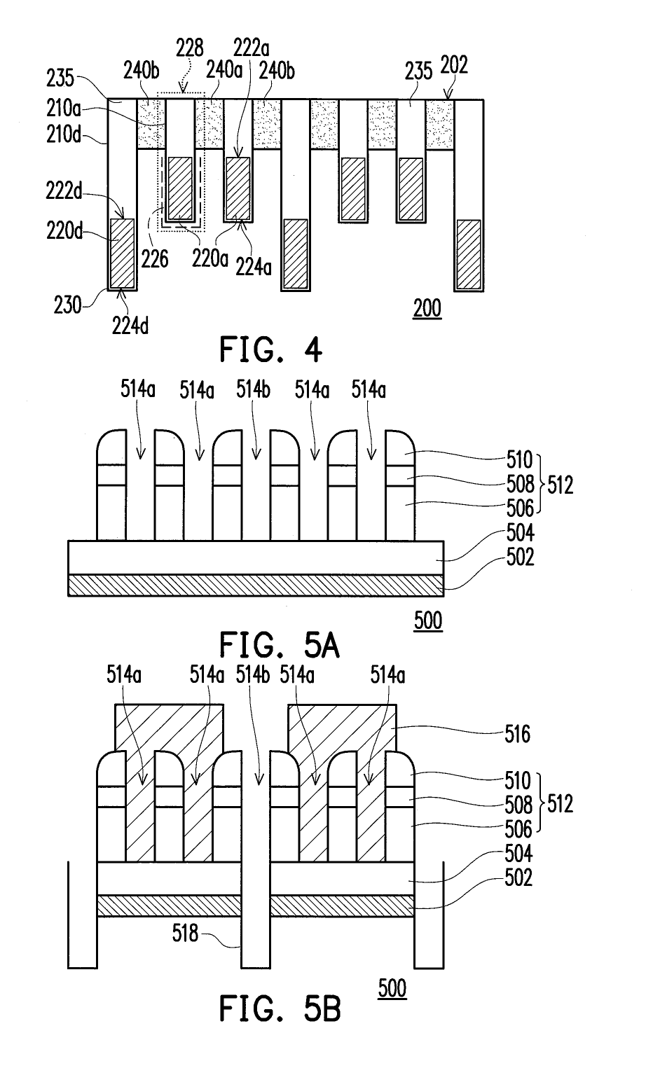

FIG. 4 is a cross-sectional view of a buried-WL DRAM structure according to the third embodiment of this invention.

Referring to FIG. 4, the third embodiment is different from the second one in that the top surfaces 222d of the isolation word lines 220d are further lower than the top surfaces 222a of the cell word lines 220a and are substantially coplanar with the bottom surfaces 224a of the cell word lines 220a. The top surfaces 222d of the isolation word lines 220d may even be lower than the bottom surfaces 224a of the cell word lines 220a. It is feasible that the bottom surfaces 224d of the isolation word lines 220d are lower than the bottom surfaces 224a of the cell word lines 220a by no more than 800 angstroms.

In such embodiment, there is substantially no overlap area between the isolation word lines 220d and the cell word lines 220a, so that the parasitic capacitance between the isolation word lines 220d and the cell word lines 220a is minimized.

On the other hand, the fabricating process of a buried-WL DRAM structure of this invention features the formation of two groups of trenches with two different depths, wherein the shallower trenches are for forming the cell word lines and the deeper ones for forming the isolation word line. The first and the second trenches with different depths can be defined by one or two lithography processes, as exemplified below.

### Embodiments 4-5: Fabrication of Buried-WL DRAM Structure

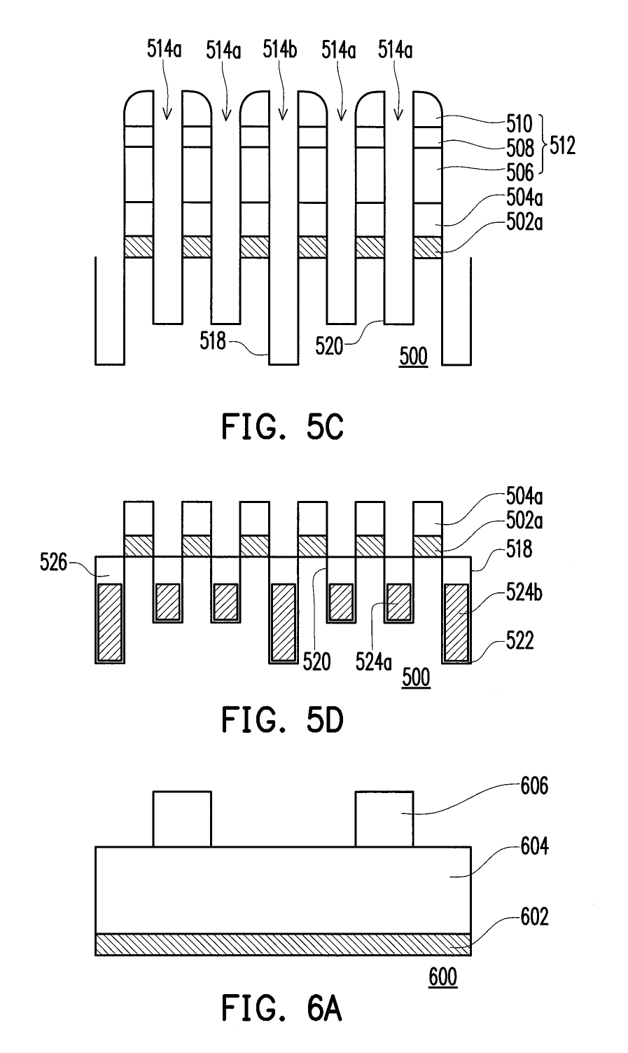

FIGS. 5A-5D illustrate, in a cross-sectional view, a fabricating process of a buried-WL DRAM structure according to a fourth embodiment of this invention, wherein the trenches of different depths are defined by two lithography processes.

Referring to FIG. 5A, a conductive layer 502, a hard mask layer 504, a TC or AC layer 506, a dielectric anti-reflection coating (DARC) 508 are formed in sequence over a semiconductor substrate 500, such as a single-crystal silicon substrate or an epitaxial silicon substrate. Spacer patterns 510 for defining the trenches are then formed on the DARC 508, possibly by forming a plurality of patterns with a double pitch and defined by a first lithography process, depositing a conformal layer, conducting anisotropic etching to the conformal layer, and removing the double-pitch patterns. Such spacer patterns 510 may be replaced by patterns with the same pitch directly defined by a lithography process, if only the lithographic resolution is enough.

The DARC 508 and the TC/AC layer 506 are then etched in sequence using the spacer patterns 510 as a mask to form a first mask layer 512, which has therein trench patterns 514a for defining the trenches of the cell word lines and trench patterns 514b for defining the trenches of the isolation word lines.

The conductor layer 502 is for the formation of periphery devices (not shown), and may include doped poly-Si or undoped poly-Si. The hard mask layer 504 may include silicon nitride (SiN) or SiO₂. The TC/AC layer 506 is for the etching of the hard mask layer 504. The DARC 508 may include SiON. The spacer patterns 510 may include silicon oxide or SiN.

It is noted that though the first mask layer 512 includes three layers (506, 508 and 510) in this embodiment, the first mask layer may alternatively consists of a single layer or two layers. For example, the first mask layer may consist of a single layer of spacer patterns formed in a similar way as in the case of the above spacer patterns 510.

Referring to FIG. 5B, a second mask layer 516 defined by a second lithography process is formed over the substrate 500, covering the patterns 514a of the trenches for forming the cell word lines. The second mask layer 516 may include a photoresist material. The hard mask layer 504, the conductor layer 502 and the substrate 500 are then etched in sequence using the first mask layer 512 and second mask layer 516 as a mask to form, in the substrate 500, a plurality of trenches 518 for forming the isolation word lines after being deepened in a later step.

Referring to FIG. 5C, the second mask layer 516 is removed. When the second mask layer 516 includes a photoresist material, it can be removed by solvent stripping or plasma ashing. The hard mask layer 504, the conductor layer 502 and the substrate 500 under the trench patterns 514a for forming the cell word lines are etched in sequence, and the portions of the substrate 500 having been exposed in the existing trenches 518 are further etched, using the first mask layer 512 as a mask. As a result, a plurality of trenches 520 for forming the cell word lines are formed in the substrate 500, and the trenches 518 for forming the isolation word lines are deepened to the required depth.

Referring to FIG. 5D, the first mask layer 512 is removed, and a gate dielectric layer 522 is formed in the trenches 520 and the deeper trenches 518. The gate dielectric layer 522 may include silicon dioxide, and may be formed through thermal oxidation. A plurality of cell word lines 524a are then formed in the trenches 520 and a plurality of isolation word lines 524b formed in the deeper trenches 518, wherein each of the word lines 524a and 524b is separated from the substrate 500 by the gate dielectric layer 522. Then, an insulator 526 is formed to seal each of the trenches 518 and 520. The insulator 526 may include PECVD oxide, SiN or SOD. The remaining hard mask layer 504a is removed in subsequent processes.

The cell word lines 524a and the isolation word lines 524b may be formed by forming a conductive layer (not shown) filling up all the trenches 518 and 520 and then etching back the conductive layer to a predetermined level.

When the cell word lines 524a and the isolation word lines 524b are designed to have coplanar top surfaces as shown in FIG. 5D or 2, the etching-back can be done in a single step. When the isolation word lines 524b are designed to have top surfaces lower than those of the cell word lines 524a as shown in FIG. 3 or 4, the etching-back can be done in two steps. For example, the portions of the conductive layer over and in the deeper trenches 518 for forming the isolation word lines are etched back firstly while those over and in the trenches 520 for forming the cell word lines are masked, and then the remaining portions of the conductive layer in the trenches 518 and the portions of the conductive layer over and in the trenches 520 are etched simultaneously.

It is noted that the subsequent process of forming source/drain (S/D) regions and the bit lines and storage capacitors coupled to the S/D regions is not illustrated in the drawings, because it is well known to a person of ordinary skill in the art.

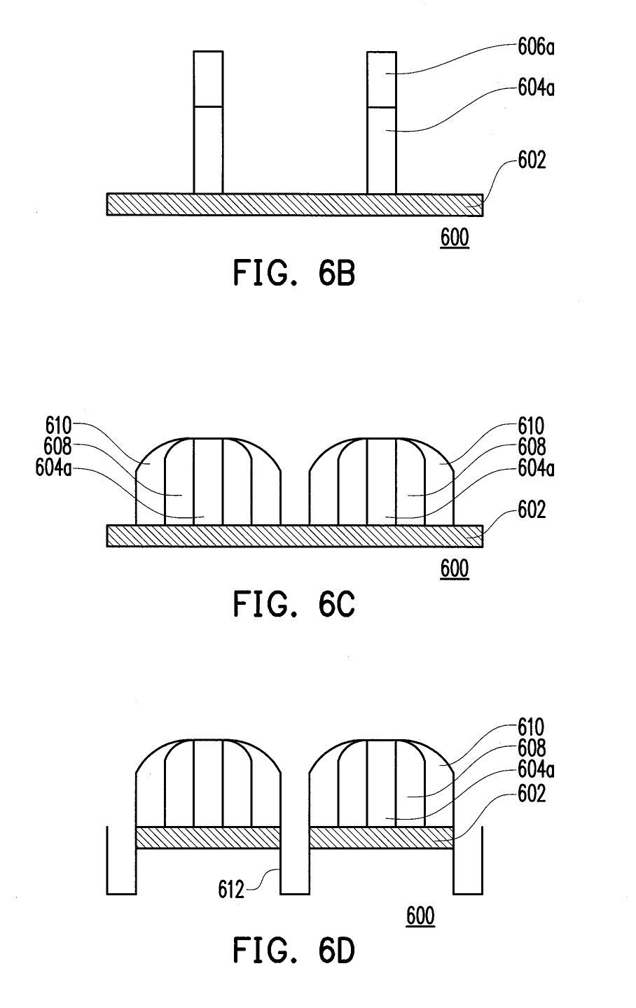

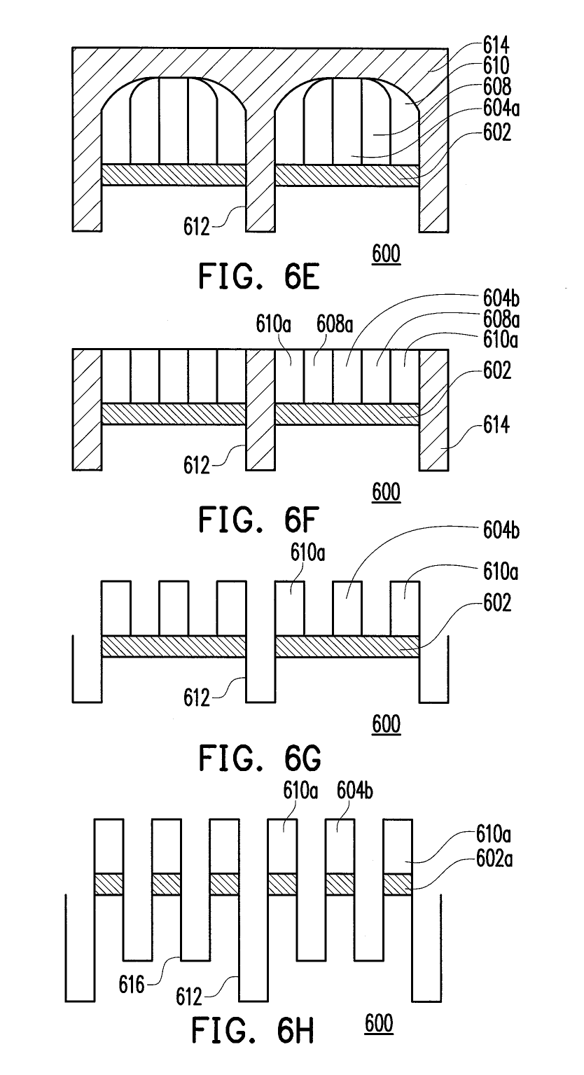

FIGS. 6A-6H illustrate, in a cross-sectional view, a fabricating process of a buried-WL DRAM structure according to a fifth embodiment of this invention, wherein the trenches of different depths are defined by one lithography process.

Referring to FIG. 6A, over a substrate 600, a conductive layer 602, a hard mask layer 604 and photoresist patterns 606 are formed in sequence. The conductive layer 602 may include doped poly-Si or undoped Poly-Si. The hard mask layer 604 may include SiN or SiO₂. The photoresist patterns 606 are defined by one lithography process.

Referring to FIG. 6B, each of the photoresist patterns 606 is trimmed narrower, possibly through dry etching. The hard mask layer 604 is then etch-patterned using the trimmed photoresist patterns 606a as a mask to form hard mask patterns 604a.

Referring to FIG. 6C, the trimmed photoresist layer 606a is removed, possibly through solvent stripping or plasma ashing. A first spacer 608 is then formed on the sidewalls of each hard mask pattern 604a, possibly by depositing a substantially conformal film of the same material and then anisotropically etching the same. A second spacer 610 is then formed on the sidewall of each first spacer 608, possibly by a similar deposition-anisotropic etching procedure. The deposition for forming the first spacers 608 or the second spacers 610 may include an atomic layer deposition (ALD) process to make a precise control on the thickness of the conformal film (=width of each spacer 608/610).

The materials of the first spacers 608 and the second spacers 610 depend on that of the hard mask patterns 604a, wherein the material of the first spacers 608 requires a much higher etching selectivity than those of the hard mask patterns 604a and second spacers 610 in a certain etchant so that the first spacers 608 can be removed by wet etching without loss of the hard mask patterns 604a and the second spacers 610. For example, when the mask patterns 604a include SiN, it is feasible that the first spacers 608 include silicon oxide and the second spacers 610 include. SiN.

Referring to FIG. 6D, the conductive layer 602 and the substrate 600 are etched using the mask patterns 604a, the first spacers 608 and the second spacers 610 as a mask to form, in the substrate 600, a plurality of trenches 612 for forming isolation word lines after being deepened in a later step.

Referring to FIG. 6E, a filling material 614 is formed over the substrate 600 filling up the trenches 612. The filling material 614 may be a photoresist material, SiO₂, SiN or SOD. This step is for preventing contamination to the trenches 612 in the subsequent removal step, and may be omitted if the removal is conducted in a manner such that the trenches 612 are substantially not contaminated.

Referring to FIG. 6F, top portions of the hard mask patterns 604a, top portions of the first spacers 608, top portions of the second spacers 610 and top portions of the filling material 614 are removed, such that the remaining hard mask patterns 604a, first spacers 608, second spacers 610 and filling material 614 have co-planar top surfaces and each of the remaining first spacers 608a and the remaining second spacers 610a has a nearly rectangular shape. The removal may include a chemical mechanical polishing (CMP) process.

Referring to FIG. 6G the filling material 614 and the remaining first spacers 608a are removed. When the filling material 614 is a photoresist material, for example, it can be removed through solvent stripping or plasma ashing. When the first spacers 608a include silicon oxide, for example, they can be removed using hydrofluoric acid (HF).

Referring to FIG. 6H, the conductive layer 602 and the substrate 600 are etched using the remaining mask patterns 604b and the remaining second spacers 610a as a mask to form a plurality of trenches 616 for forming the cell word lines and deepen the existing trenches 612 for forming the isolation word lines.

Thereafter, a gate dielectric layer, cell word lines and isolation word lines, and a trench-sealing insulator are formed (not shown) as in the fourth embodiment, possibly in a manner similar to the manner in which the gate dielectric layer 520, the cell word lines 524a, the isolation word lines 524b and the trench-sealing insulator 526 are formed as described in the paragraphs relating to FIG. 5D.

In a case of this embodiment, the ratio of the distance between two neighboring hard mask patterns 604a to the width of each hard mask pattern 604a is equal to 5 (FIG. 6B), and each first spacer 608 or second spacer 610 has the same width as each hard mask pattern 604a (FIG. 6C). As a result, the width of the gap between two opposite second spacers 610 (FIG. 6C) for defining a trench 612 (FIG. 6D) of an isolation word line is the same as that of each remaining first spacer 608a (FIG. 6F) for defining a trench 616 (FIG. 6H) of a cell word line, and thus the width of each trench 612 or the isolation word line formed therein is the same as that of each trench 616 or the cell word line formed therein (FIG. 6H).

The subsequent process of forming S/D regions, bit lines and capacitors is either not illustrated here since it is well known to a person of ordinary skill in the art.

It is also noted that although a conductive layer (502 or 602) is formed on the substrate before the hard mask layer (504 or 604) is formed in the above embodiments for etch stopping in patterning the hard mask layer 504/604 and for the gate electrodes of periphery devices, the conductive layer may alternatively be omitted when the gate electrodes of the periphery devices are formed after the buried WLs are defined.

Since the bottom surfaces of the isolation word lines are lower than those of the cell word lines in the buried-WL DRAM structure of this invention, the isolation effect between adjacent cells is improved as compared to the prior art where the bottom surfaces of the isolation word lines are coplanar with those of the cell word lines.

Moreover, when the top surfaces of the isolation word lines are lower than those of the cell word lines, the parasitic capacitance between the isolation word lines and the cell word lines and that between the isolation word lines and the bit lines are both decreased. Consequently, the performance of the DRAM can be further improved.

It is also noted that though the above fabricating process is for forming cell word lines and deeper isolation word lines buried in the substrate for a DRAM structure, it can also be applied to the fabrication of other IC structures with buried conductors to form trenches with different depths and thereby make different depths for the buried conductors.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

What is claimed is:

1. A DRAM structure with buried word lines, comprising:
a semiconductor substrate;
a plurality of cell word lines buried in the substrate and separated from the substrate by a first gate dielectric layer; and
a plurality of isolation word lines buried in the substrate and separated from the substrate by a second gate dielectric layer,
wherein top surfaces of the cell word lines and top surfaces of the isolation word lines are lower than a top surface of the substrate, bottom surfaces of the isolation word lines are lower than bottom surfaces of the cell word lines, and the top surfaces of the isolation word lines are lower than the top surfaces of the cell word lines.

2. The DRAM structure of claim 1, wherein the top surfaces of the isolation word lines are higher than the bottom surfaces of the cell word lines.

3. The DRAM structure of claim 1, wherein the top surfaces of the isolation word lines are substantially coplanar with the bottom surfaces of the cell word lines, or are lower than the bottom surfaces of the cell word lines.

4. The DRAM structure of claim 1, wherein the cell word lines are divided into a plurality of pairs of cell word lines, and each pair of cell word lines is separated from a neighboring pair of cell word lines by an isolation word line.

5. The DRAM structure of claim 1, wherein the cell word lines and the isolation word lines comprise a metallic material.

6. The DRAM structure of claim 5, wherein the metallic material comprises TiN, TaN, W or poly-Si.

7. The DRAM structure of claim 1, wherein the first gate dielectric layer and the second gate dielectric layer comprise silicon dioxide or SiN.

8. The DRAM structure of claim 1, wherein the top surfaces of the cell word lines are lower than the top surface of the substrate by about 700-800 angstroms, and a thickness of the cell word lines is about 700-800 angstroms.

9. The DRAM structure of claim 8, wherein the bottom surfaces of the isolation word lines are lower than the bottom surfaces of the cell word lines by no more than 800 angstroms.

10. A integrated circuit (IC) structure with buried conductors, comprising:
a substrate;
a plurality of first conductors buried in the substrate; and
a plurality of second conductors buried in the substrate, wherein bottom surfaces of the second conductors are lower than bottom surfaces of the first conductors, and the top surfaces of the second conductors are lower than the top surfaces of the first conductors.

11. The IC structure of claim 10, wherein top surfaces of the first conductors and top surfaces of the second conductors are lower than a top surface of the substrate.

12. The IC structure of claim 11, wherein the top surfaces of the second conductors are higher than the bottom surfaces of the first conductors.

13. The IC structure of claim 11, wherein the top surfaces of the second conductors are substantially coplanar with the bottom surfaces of the first conductors, or are lower than the bottom surfaces of the first conductors.

14. The IC structure of claim 10, wherein the integrated circuit comprises a memory, the substrate comprises a semiconductor substrate, the first conductors comprise a plurality of cell word lines, and the second conductors comprise isolation word lines, the IC structure further comprising:
a gate dielectric layer, separating each of the cell word lines and the isolation word lines from the substrate.
